(19) United States
(12) Patent Application Publication
(10) Pub. No.: US 2020/0044650 A1
(43) Pub. Date: Feb. 6, 2020

(54) SWITCH APPARATUS

(71) Applicant: FUJI ELECTRIC CO., LTD., Kanagawa (JP)

(72) Inventors: Satoru FUJITA, Tachikawa-City (JP); Ryuji YAMADA, Hachioji-city (JP)

(21) Appl. No.: 16/455,806

(22) Filed: Jun. 28, 2019

(30) Foreign Application Priority Data
Aug. 6, 2018 (JP) 2018-147990

(51) Int. Cl. H03K 17/693; H01H 9/54; H01H 33/59; H01R 13/703; H02H 3/087; H03K 17/0814; H03K 17/12

(52) U.S. Cl. CPC H03K 17/693; H01H 9/54; H01H 33/59; H01H 2009/544; H02H 3/087; H03K 17/08142; H03K 17/122; H01R 13/703

(57) ABSTRACT

Provided is a switch apparatus that provides a connection or a disconnect between an input terminal and an output terminal, including a mechanical switch section and a first semiconductor switch section that are connected in series, between the input terminal and the output terminal; a second semiconductor switch section that is connected in parallel with the mechanical switch section and the first semiconductor switch section, between the input terminal and the output terminal; and a switch control section that individually controls respective ON/OFF timings of the first semiconductor switch section and the second semiconductor switch section and an open/close timing of the mechanical switch section.

The contents of the following Japanese patent application are incorporated herein by reference:

NO. 2018-147990 filed on Aug. 6, 2018

### BACKGROUND

### 1. Technical Field

The present invention relates to a switch apparatus.

### 2. Related Art

Technology is known whereby, in a switch including a mechanical switch and a semiconductor switch connected to each other in parallel, the mechanical switch and the semiconductor switch are normally ON, such that current flows through the mechanical switch side, and when the current is cut off, the mechanical switch is turned OFF and then the semiconductor switch is turned OFF, as shown in Patent Documents 1 and 2, for example. Furthermore, technology is known whereby, in a DC circuit breaker including a mechanical switch having a gas disconnector and a vacuum circuit breaker, a forced commutation circuit connected in parallel to the vacuum circuit breaker, and a semiconductor switch (e.g. an IGBT) connected in parallel to the mechanical switch, current normally flows through the mechanical switch, and when the current is cut off, a current in the opposite direction of the DC current flowing through the vacuum circuit breaker flows from the forced commutation circuit, thereby generating a current zero point in the vacuum circuit breaker and making it non-conductive, and due to this, current is commutated from the mechanical switch to the IGBT and, after the current flowing through the gas disconnector has dissipated, the gas disconnector opens to set the IGBT to a non-conductive state, as shown in Patent Document 3, for example.

### Patent Document 1: International Publication WO 2011/034140

### Patent Document 2: Japanese Patent Application Publication No. 2017-191764

### Patent Document 3: International Publication WO 2016/047209

According to the DC circuit breaker described above, it is possible to mostly avoid arcing in the gas disconnector when overcurrent occurs, but the IGBT is turned OFF after the vacuum circuit breaker and the gas disconnector are mechanically turned OFF. During the OFF interval of the DC circuit breaker, which includes the interval until the vacuum circuit breaker and gas disconnector are mechanically turned OFF, the current flowing through the IGBT increases due to the interval until the vacuum circuit breaker and gas disconnector are mechanically turned OFF being long. In the IGBT, the collector current is saturated at five times or less the rated current, and a forward voltage drop increases up to, at the maximum, an amount equivalent to the power supply voltage. Accordingly, in the DC circuit breaker described above, it is necessary to increase the current capacity of the IGBT to a level that does not result in saturation even when overcurrent occurs, in order for the IGBT to have a circuit breaking capability for the overcurrent, and this ends up increasing both the cost and the size of the apparatus.

### SUMMARY

A switch apparatus that provides a connection or a disconnect between an input terminal and an output terminal may comprise a mechanical switch section, a first semiconductor switch section, a second semiconductor switch section, and a switch control section. The mechanical switch section and the first semiconductor switch section may be connected in series, between the input terminal and the output terminal. The second semiconductor switch section may be connected in parallel with the mechanical switch section and the first semiconductor switch section, between the input terminal and the output terminal. The switch control section may individually control respective ON/OFF timings of the first semiconductor switch section and the second semiconductor switch section and an open/close timing of the mechanical switch section.

The switch apparatus may further comprise a current detecting section provided between the input terminal and the output terminal. The switch control may include a protection circuit, a pulse distribution circuit, and a drive circuit. The protection circuit may output OFF instructions when overcurrent is detected in response to a signal from the current detecting section. The pulse distribution circuit may, based on a signal from outside, output a predetermined pulse signal for opening/closing the mechanical switch section and turning ON/OFF each of the first semiconductor switch section and the second semiconductor switch section, and when the OFF instructions are input from the protection circuit, output a predetermined pulse signal for closing the mechanical switch section and turning OFF each of the first semiconductor switch section and the second semiconductor switch section, regardless of the signal from the outside. The drive circuit may, based on the pulse signal input from the pulse distribution circuit, output a signal for opening/closing the mechanical switch section and gate voltages for respectively turning ON/OFF the first semiconductor switch section and the second semiconductor switch section.

A withstand voltage of the first semiconductor switch section may be higher than an ON voltage of the second semiconductor switch section.

The first semiconductor switch section may include a plurality of first semiconductor switches connected in parallel between the input terminal and the output terminal. The second semiconductor switch section may include a plurality of second semiconductor switches connected in series between the input terminal and the output terminal. A withstand voltage of each of the plurality of the first semiconductor switches may be higher than a sum of ON voltages of the plurality of second semiconductor switches.

The switch control section, with each of the first semiconductor switch section, the mechanical switch section, and the second semiconductor switch section in the ON state, when switching a state between the input terminal and the output terminal from a connected state to a disconnected state, may turn OFF the first semiconductor switch section, the mechanical switch section, and the second semiconductor switch section in the stated order.

The switch control section, when switching the state between the input terminal and the output terminal from the connected state to the disconnected state, may turn OFF the first semiconductor switch section, and then turn OFF the mechanical switch section in response to current of the first semiconductor switch section becoming less than or equal to a predetermined value.

The switch control section, with each of the first semiconductor switch section, the mechanical switch section, and the second semiconductor switch section in the OFF state, when changing a state between the input terminal and the output terminal from a disconnected state to a connected state, may turn ON the second semiconductor switch section, the mechanical switch section, and the first semiconductor switch section in the stated order.

The switch control section may turn ON the second semiconductor switch section, and then turn ON the mechanical switch section in response to a potential difference between the input terminal and the output terminal becoming less than or equal to a reference.

A switch apparatus may comprise a mechanical switch, a first semiconductor switch section, a second semiconductor switch section, a third semiconductor switch section, and a switch control section. The mechanical switch may switch between a connected state between a first input terminal and an output terminal and a connected state between a second input terminal and the output terminal. The first semiconductor switch section may be connected in series with the mechanical switch, between the first input terminal and the output terminal and between the second input terminal and the output terminal. The second semiconductor switch section may be connected in parallel with the mechanical switch and the first semiconductor switch section, between the first input terminal and the output terminal. The third semiconductor switch section may be connected in parallel with the mechanical switch and the first semiconductor switch section, between the second input terminal and the output terminal. The switch control section may individually control respective ON/OFF timings of the first semiconductor switch section, the second semiconductor switch section, and the third semiconductor switch section and an open/close timing of the mechanical switch.

The switch control section, with the first semiconductor switch section and the second semiconductor switch section in an ON state and the mechanical switch providing a connected state between the first input terminal and the first semiconductor switch section, when switching the state between the first input terminal and the output terminal from the connected state to a disconnected state and switching the state between the second input terminal and the output terminal from the disconnected state to the connected state, may turn OFF the first semiconductor switch section, then cause the mechanical switch to switch to the connected state between the second input terminal and the first semiconductor switch section, then turn OFF the second semiconductor switch section and turns ON the third semiconductor switch section, and then turn ON the first semiconductor switch section.

The switch control section, with the first semiconductor switch section and the second semiconductor switch section in the ON state and the mechanical switch providing the connected state between the first input terminal and the first semiconductor switch section, when switching the state between the first input terminal and the output terminal from the connected state to a disconnected state and switching the state between the second input terminal and the output terminal from the disconnected state to the connected state, may turn OFF the first semiconductor switch section, then cause the mechanical switch to switch to the disconnected state between the first input terminal and the first semiconductor switch section and between the second input terminal and the first semiconductor switch section, then turn OFF the second semiconductor switch section and turn ON the third semiconductor switch section, then cause the mechanical switch to switch to the connected state between the second input terminal and the first semiconductor switch section, and then turn ON the first semiconductor switch section.

The switch control section may turn ON the third semiconductor switch section, and then cause the mechanical switch to switch to the connected state between the second input terminal and the first semiconductor switch section in response to a potential difference between the second input terminal and the output terminal becoming less than or equal to a reference.

The first semiconductor switch section may include a plurality of first semiconductor switches. The plurality of first semiconductor switches may be connected in anti-series between the input terminal and the output terminal, and may each include a set of a semiconductor switch element and a diode connected in antiparallel between the input terminal and the output terminal. The switch apparatus may further comprise a diode bridge. The diode bridge may be connected in parallel with the second semiconductor switch section, between the input terminal and the output terminal.

The first semiconductor switch section may include a plurality of first semiconductor switches. The plurality of first semiconductor switches may be connected in anti-series between the first input terminal and the output terminal, and may each include a set of a semiconductor switch element and a diode connected in antiparallel between the first input terminal and the output terminal. The switch apparatus may further comprise a first diode bridge and a second diode bridge. The first diode bridge may be connected in parallel with the second semiconductor switch section, between the first input terminal and the output terminal. The second diode bridge may be connected in parallel with the third semiconductor switch section, between the second input terminal and the output terminal.

The first semiconductor switch section may include a MOSFET, and the second semiconductor switch section may include at least one of an IGBT, a GTO thyristor, and a WBG semiconductor.

The first semiconductor switch section may include a MOSFET, and at least one of the second semiconductor switch section and the third semiconductor switch section may include at least one of an IGBT, a GTO thyristor, and a WBG semiconductor.

The summary clause does not necessarily describe all necessary features of the embodiments of the present invention. The present invention may also be a sub-combination of the features described above.

### BRIEF DESCRIPTION OF THE DRAWINGS

FIG. 1 is a schematic circuit diagram of a switch apparatus 10 according to a first embodiment.

FIG. 2 is a timing chart showing the operation of the switch section 100 according to the first embodiment.

FIG. 3 is a schematic circuit diagram of a switch section 200 according to a second embodiment.

FIG. 4 is a schematic circuit diagram of a switch section 300 according to a third embodiment.

FIG. 5 is a timing chart showing the operation of the switch section 300 according to the third embodiment.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention. In the drawings, there are cases with identical or similar portions are given the same reference numerals, and redundant descriptions are omitted.

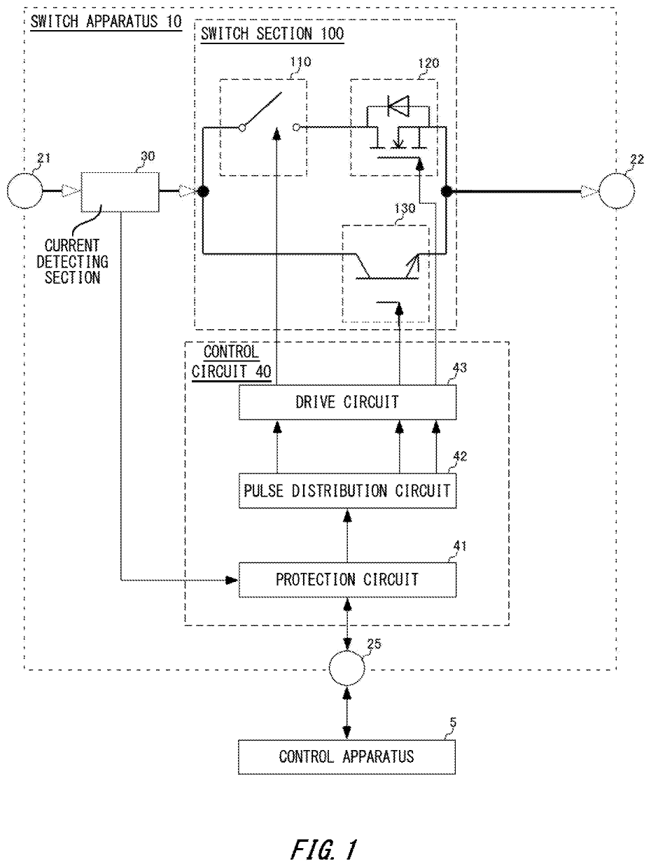

FIG. 1 is a schematic circuit diagram of a switch apparatus 10 according to a first embodiment. In the drawing, the black-tipped arrows indicate the input/output direction of control signals, and the white-tipped arrows indicate the direction of the flow of power. The same is also true in the following drawings.

The switch apparatus 10 includes a first terminal 21, a second terminal 22, a control terminal 25, a switch section 100, a current detecting section 30, and a control circuit 40. The first terminal 21 is an example of an input terminal, and the second terminal 22 is an example of an output terminal. The switch apparatus 10 conducts or cuts off the DC current that attempts to flow from the first terminal 21 to the second terminal 22, by providing a connection or a disconnect between the first terminal 21 and the second terminal 22. The switch apparatus 10 may be applied to a switchboard or the like that handles DC current, and the operation of the switch apparatus 10 is controlled by an external control apparatus 5, via the control terminal 25. In commercial use, a high DC voltage such as 400 V or 800 V, for example, is applied to the switch apparatus 10.

The switch section 100 includes a mechanical switch section 110, a first semiconductor switch section 120, and a second semiconductor switch section 130.

The mechanical switch section 110 is connected between the first terminal 21 and the second terminal 22. The mechanical switch section 110 has metal contact points and, as an example, includes a mechanical relay. The mechanical switch section 110 does not need to have an arc elimination structure. The mechanical switch section 110 causes metal conductors thereof to contact or be separated from each other, and therefore has a significantly lower conduction resistance than both the first semiconductor switch section 120 and the second semiconductor switch section 130, and exhibits almost no current conduction loss even when conducting a large current. Therefore, the mechanical switch section 110 does not need cooling fins or the like for cooling the heat generated due to power loss. In the following description, there are cases where the opening/closing of the mechanical switch section 110 is referred to as the mechanical switch section 110 being turned ON/OFF.

The first semiconductor switch section 120 is connected in series with the mechanical switch section 110, between the first terminal 21 and the second terminal 22. The first semiconductor switch section 120 has a faster switching speed than the mechanical switch section 110 and the second semiconductor switch section 130. As an example, the first semiconductor switch section 120 includes a low-voltage MOSFET with a switching speed of tens of nanoseconds and an extremely low ON resistance of approximately several milliohms when the withstand voltage is on the order of tens of volts. The low-voltage MOSFET includes an internal body diode or a diode that is connected in antiparallel. The low-voltage MOSFET of the first semiconductor switch section 120 has its drain connected to the mechanical switch section 110, its source connected to the second terminal 22, and its gate connected to the control circuit 40.

The second semiconductor switch section 130 is connected in parallel with the mechanical switch section 110 and the first semiconductor switch section 120, between the first terminal 21 and the second terminal 22. The second semiconductor switch section 130 is capable of cutting off current more quickly than the mechanical switch section 110.

The withstand voltage of the first semiconductor switch section 120 described above is lower than the withstand voltage of the second semiconductor switch section 130 and higher than the ON voltage of the second semiconductor switch section 130. The ON voltage of the second semiconductor switch section 130 referred to here is the voltage occurring between the main terminals of the second semiconductor switch section 130, due to the second semiconductor switch section 130 conducting in the ON state.

The ON voltage of the second semiconductor switch section 130 is higher than the sum of the ON voltages of the mechanical switch section 110 and the first semiconductor switch section 120. The second semiconductor switch section 130 includes an IGBT, for example. The second semiconductor switch section 130 may include a GTO thyristor, a WBG semiconductor, or the like. The IGBT of the second semiconductor switch section 130 has its collector connected to the first terminal 21, its emitter connected to the second terminal 22, and its gate connected to the control circuit 40.

The current detecting section 30 is provided between the first terminal 21 and the second terminal 22, on the first terminal 21 side, i.e. the DC current input side, for example, detects the current flowing between the first terminal 21 and the second terminal 22, and outputs a signal indicating the current value to the control circuit 40. The current detecting section 30 may be an ammeter connected in series with the switch section 100 between the first terminal 21 and the second terminal 22. Alternatively, the current detecting section 30 may be a current transformer type of current sensor that detects the current flowing between the first terminal 21 and the second terminal 22 in a non-contact manner.

The control circuit 40 includes a protection circuit 41, a pulse distribution circuit 42, and a drive circuit 43. The control circuit 40 individually controls the ON/OFF timing of each of the first semiconductor switch section 120 and the second semiconductor switch section 130 and the open/close timing of the mechanical switch section 110 in the switch section 100, based on a control signal sent from the control apparatus 5. The control circuit 40 is an example of a switch control section. The control circuit 40 may be a control computer including a CPU, such as a microcontroller, and may function as each section shown below by executing a switch program. Instead, the control circuit 40 may be realized by specialized circuitry or programmable circuitry.

Concerning the mechanical switch section 110, the control circuit 40 performs control to close the mechanical switch section 110 so as to conduct the DC current, in a case where DC current is to be conducted by the switch section 100, i.e. in a normal case. Furthermore, in a case where the DC current is to be cut off by the switch section 100, the control circuit 40 controls the mechanical switch section 110 to open after the DC current conducted through the mechanical switch section 110 has been commutated to the second semiconductor switch section 130. By having the control circuit 40 control the mechanical switch section 110 in this way, arcing does not occur in the mechanical switch section 110. However, while the mechanical switch section 110 is in the closed state and the first semiconductor switch section 120 and the second semiconductor switch section 130 are in the ON state, the voltage between the first terminal 21 and the second terminal 22 is approximately from several volts to tens of volts, and therefore, instead of the control described above, the control circuit 40 may cut off the current with the mechanical switch section 110 by opening the mechanical switch section 110 without performing the commutation described above. In this case, the switch section 100 may additionally be configured to protect the mechanical switch section 110 from arcing generated by the mechanical switch section 110.

Concerning the first semiconductor switch section 120, in the normal case, the control circuit 40 controls the first semiconductor switch section 120 to be in the ON state to conduct the DC current. Furthermore, when the DC current is to be cut off by the switch section 100, the control circuit 40 turns OFF the first semiconductor switch section 120 before turning OFF the mechanical switch section 110 and the second semiconductor switch section 130, thereby performing control causing the DC current that has flowed through the first semiconductor switch section 120 side to be commutated to the second semiconductor switch section 130 side.

Concerning the second semiconductor switch section 130, in the normal case, the control circuit 40 controls the second semiconductor switch section 130 to be in the ON state. However, since the ON voltage of the second semiconductor switch section 130 is higher than the sum of the ON voltages of the mechanical switch section 110 and the first semiconductor switch section 120, the DC current barely flows through the second semiconductor switch section 130. Furthermore, when the DC current is to be cut off by the switch section 100, the control circuit 40 performs control to turn OFF the second semiconductor switch section 130 after the DC current that has flowed to the first semiconductor switch section 120 has been commutated to the second semiconductor switch section 130 side and flowed to the second semiconductor switch section 130. In the normal case, the control circuit 40 may set the second semiconductor switch section 130 to the OFF state while the DC current is flowing through the first semiconductor switch section 120 side, and in a case where the DC current is to be cut off by the switch section 100, the control circuit 40 may perform control to turn OFF the first semiconductor switch section 120 after turning ON the second semiconductor switch section 130, to perform the commutation and cutting off of the DC current in a similar manner as described above.

The protection circuit 41 is provided with a control signal for conducting the normal DC current in the switch section 100, from the external control apparatus 5 via the control terminal 25, and outputs this control signal to the pulse distribution circuit 42. The protection circuit 41 receives a signal from the current detecting section 30 at any time, and detects overcurrent according to this signal from the current detecting section 30. As an example, the protection circuit 41 detects overcurrent by judging whether a current value indicated by the signal from the current detecting section 30 is greater than or equal to a predetermined overcurrent setting value lim. If overcurrent is detected, the protection circuit 41 outputs OFF instructions to the pulse distribution circuit 42. In a case where the switch apparatus 10 does not include the current detecting section 30, the protection circuit 41 may detect the current value on the first terminal 21 side of the switch apparatus 10, i.e. the DC current input side, in which case the protection circuit 41 may include a magnetic sensor, for example, to detect this current value. Instead of outputting the OFF signal described above, the protection circuit 41 may stop the supply of the control signal described above to the pulse distribution circuit 42.

The pulse distribution circuit 42 outputs to the drive circuit 43 a predetermined pulse signal for opening/closing the mechanical switch section 110 and turning ON/OFF each of the first semiconductor switch section 120 and the second semiconductor switch section 130, based on a control signal from the external control apparatus 5 input to the pulse distribution circuit 42 via the protection circuit 41. When the OFF instructions are input from the protection circuit 41, the pulse distribution circuit 42 outputs to the drive circuit 43 the predetermined pulse signal for closing the mechanical switch section 110 and turning OFF each of the first semiconductor switch section 120 and the second semiconductor switch section 130, regardless of the control signal from the external control apparatus 5. The pulse distribution circuit 42 outputs to the drive circuit 43 a pulse signal obtained by applying a predetermined delay time or time difference to the control signal from the external control apparatus 5 input to the pulse distribution circuit 42 via the protection circuit 41. In this way, the timings of the open/close operation of the mechanical switch section 110 and the ON/OFF operation of each of the first semiconductor switch section 120 and the second semiconductor switch section 130 are shifted relative to each other.

The drive circuit 43 outputs a signal for opening/closing the mechanical switch section 110 and gate voltages for turning ON/OFF each of the first semiconductor switch section 120 and the second semiconductor switch section 130, based on the pulse signal input from the pulse distribution circuit 42, i.e. at timings corresponding to the delay time or the like applied to the control signal described above.

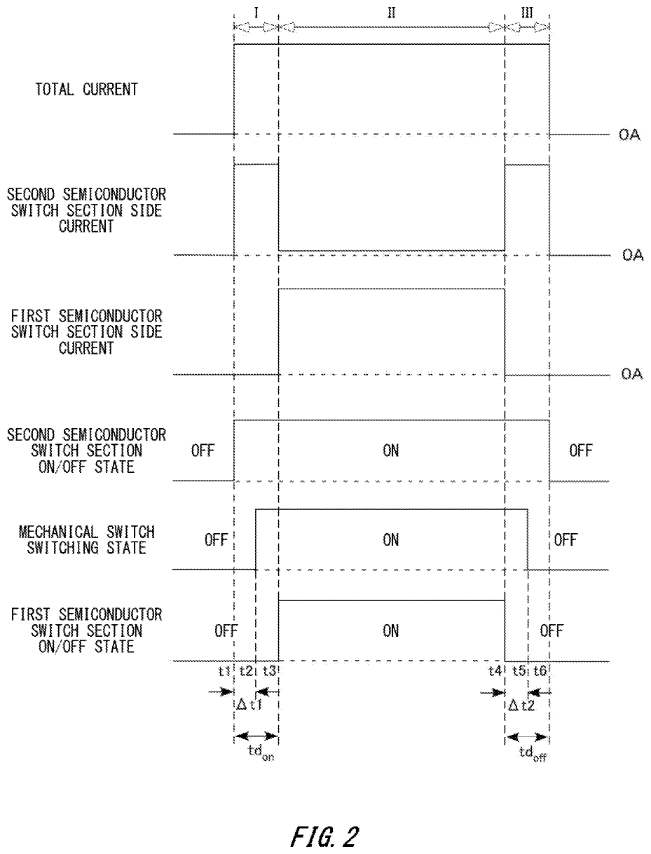

FIG. 2 is a timing chart showing the operation of the switch section 100 according to the first embodiment. FIG. 2 shows the passage of time in the horizontal direction, and shows the transitioning over time of the total current, the current on the second semiconductor switch section 130 side, the current on the first semiconductor switch section 120 side, the ON/OFF state of the second semiconductor switch section 130, the ON/OFF state of the mechanical switch section 110, and the ON/OFF state of the first semiconductor switch section 120 in the stated order from the top in the vertical direction. Furthermore, FIG. 2 shows intervals (I), (II), and (III), obtained by dividing the elapsed time into three main intervals, in the stated order from the left.

The interval (I) is an interval during which a transition is made from a state where the DC current is cut off by the switch section 100 to a state in which the DC current is conducted by the switch section 100. The interval (II) is an interval during which the DC current is conducted regularly by the switch section 100. The interval (III) is an interval during which a transition is made from the state where the DC current is conducted by the switch section 100 to the state in which the DC current is cut off by the switch section 100. In order to make the description clear, in FIG. 2, the interval (II) is shown to be short. Furthermore, in the time sequence in FIG. 2, the intervals before the interval (I) and after the interval (III) are intervals during which the DC current is cut off by the switch section 100, and any of the intervals (I), (II), and (III) may be included in the intervals not shown in the drawing.

At the initial timing t1 in the interval (I), with the mechanical switch section 110, the first semiconductor switch section 120, and the second semiconductor switch section 130 each in the OFF state, the gate voltage of the IGBT of the second semiconductor switch section 130 is controlled from the control circuit 40 to turn ON only the second semiconductor switch section 130. The IGBT is a semiconductor element capable of a relatively high-speed switching operation, and can therefore quickly enter the ON state, making it possible to speed up the ON operation of the entire switch apparatus 10. When only the second semiconductor switch section 130 is in the ON state, the DC current starts flowing only through the second semiconductor switch section 130 side.

The next timing t2 in the interval (I) has a time difference of Δt1 relative to the timing t1. The time difference Δt1 only needs to be enough to ensure the time necessary for the IGBT of the second semiconductor switch section 130 to turn ON, i.e. the time until the turn-ON operation is completed and the regular DC current is conducted through the IGBT. As an example, the time difference Δt1 is approximately from 1 μs to 2 μs. At the timing t2, the mechanical switch section 110 is turned ON from the control circuit 40. At this time, the first semiconductor switch section 120 connected in series with the mechanical switch section 110 is still in the OFF state, and therefore even though the mechanical switch section 110 is turned ON, the DC current does not flow through the first semiconductor switch section 120 side and flows only through the second semiconductor switch section 130 side. Therefore, arcing does not occur in the mechanical switch section 110. Furthermore, by providing the time difference Δt1, even when the mechanical switch section 110 is turned ON, the DC voltage applied to the first semiconductor switch section 120 is approximately tens of volts, which is the ON voltage of the IGBT of the second semiconductor switch section 130, and therefore a low-voltage MOSFET can be used in the first semiconductor switch section 120.

The initial timing t3 in the interval (II) has a delay time tdₒₙ relative to the timing t1. At the timing t3, the gate voltage of the low-voltage MOSFET of the first semiconductor switch section 120 is controlled from the control circuit 40 to turn ON the first semiconductor switch section 120. Since the sum of the ON voltages of the mechanical switch section 110 and the first semiconductor switch section 120 is lower than the ON voltage of the second semiconductor switch section 130, at the timing t3, the DC current that flowed through the second semiconductor switch section 130 side is commutated to the first semiconductor switch section 120 side, such that the DC current barely flows through the second semiconductor switch section 130 side. The difference between the delay time tdₒₙ and the time difference Δt1 only needs to be enough to ensure the time needed for the mechanical switch section 110 to close. If the first semiconductor switch section 120 is turned ON before the mechanical switch section 110 closes, arcing occurs when the mechanical switch section 110 closes, but with the control described above, it is possible to reliably avoid the occurrence of arcing in the mechanical switch section 110.

In the interval (II), the ratio between the DC current flowing through the first semiconductor switch section 120 side and the DC current flowing through the second semiconductor switch section 130 side corresponds to the ratio between the sum of the ON voltages of the mechanical switch section 110 and first semiconductor switch section 120 and the ON voltage of the second semiconductor switch section 130. Accordingly, the DC current ratio described above may be adjusted by changing the number of parallel semiconductor switch elements, for example. As an example, the ON resistance of the first semiconductor switch section 120 may be decreased by connecting a plurality of low-voltage MOSFETs in parallel in the first semiconductor switch section 120, thereby reducing the DC current flowing through the second semiconductor switch section 130 side. Furthermore, in the second semiconductor switch section 130, the tradeoff relationship between switching speed and ON resistance may be utilized to select semiconductor switch elements that prioritize switching speed to intentionally increase the ON resistance, thereby reducing the DC current flowing through the second semiconductor switch section 130 side.

At the initial timing t4 in the interval (III), with the mechanical switch section 110, the first semiconductor switch section 120, and the second semiconductor switch section 130 each in the ON state, the gate voltage of the low-voltage MOSFET of the first semiconductor switch section 120 is controlled from the control circuit 40 to turn OFF only the first semiconductor switch section 120. Since the low-voltage MOSFET has a switching speed of tens of nanoseconds, the low-voltage MOSFET can be quickly set to the OFF state. By setting the first semiconductor switch section 120 to the OFF state, the first semiconductor switch section 120 side is completely cut off, and the DC current that flowed through the first semiconductor switch section 120 side is commutated to the second semiconductor switch section 130. By turning OFF the first semiconductor switch section 120 while keeping the mechanical switch section 110 and the second semiconductor switch section 130 in the ON state, the DC voltage applied to the first semiconductor switch section 120 becomes approximately tens of volts, which is the ON voltage of the IGBT of the second semiconductor switch section 130, and so it is possible to use a low-voltage MOSFET in the first semiconductor switch section 120.

The next timing T5 in the interval (III) has a time difference Δt2 relative to the timing t4. The time difference Δt2 only needs to be enough to ensure the time necessary for the low-voltage MOSFET of the first semiconductor switch section 120 to turn OFF, i.e. the time until the turn-OFF operation is completed and the DC current that flowed through the first semiconductor switch section 120 side is commutated to the second semiconductor switch section 130 side. As an example, the time difference Δt2 is approximately from 1 μs to 2 μs. At the timing t5, the mechanical switch section 110 is turned OFF from the control circuit 40. At this time, the DC current is not flowing through the first semiconductor switch section 120 side, and therefore arcing does not occur in the mechanical switch section 110.

The next timing t6 in the interval (III) has a delay time td_{off} relative to the timing t4. At the timing t6, the gate voltage of the IGBT of the second semiconductor switch section 130 is controlled from the control circuit 40 to turn OFF the second semiconductor switch section 130, thereby completely cutting off the DC current flowing through the switch section 100. The IGBT is a semiconductor switch element capable of a relatively high-speed switching operation, and can therefore quickly enter the OFF state, making it possible to speed up the OFF operation of the entire switch apparatus 10 when overcurrent occurs.

The difference between the delay time td_{off} and the time difference Δt2 only needs to be enough to ensure the time needed for the mechanical switch section 110 to open. If the second semiconductor switch section 130 is turned OFF before the mechanical switch section 110 opens, the high voltage of the system is applied to the low-voltage MOSFET of the first semiconductor switch section 120 via the first terminal 21 and overvoltage breakdown occurs, but with the control described above, it is possible to reliably avoid the occurrence of overvoltage breakdown in the low-voltage MOSFET.

According to the switch apparatus 10 of the first embodiment described above, with the first semiconductor switch section 120, the mechanical switch section 110, and the second semiconductor switch section 130 in the OFF state, when the state between the first terminal 21 and the second terminal 22 is switched from the connected state to the disconnected state, the second semiconductor switch section 130, the mechanical switch section 110, and the first semiconductor switch section 120 are turned ON in the stated order. Furthermore, according to the switch apparatus 10, with the first semiconductor switch section 120, the mechanical switch section 110, and the second semiconductor switch section 130 in the ON state, when the state between the first terminal 21 and the second terminal 22 is switched from the connected state to the disconnected state, the first semiconductor switch section 120, the mechanical switch section 110, and the second semiconductor switch section 130 are turned OFF in the stated order.

In this way, the switch apparatus 10 can use a low-voltage MOSFET with a high switching speed and an extremely low ON resistance in the first semiconductor switch section 120, and since the DC current usually flows through the mechanical switch section 110 and first semiconductor switch section 120 sides, it is possible to restrict current conduction loss. Furthermore, since an arc elimination structure is not needed in the mechanical switch section 110, it is possible to realize a smaller size and reduced cost. Since there is no deterioration at the metal contact points caused by arcing in the mechanical switch section 110, the lifespan can be increased. By using the configuration in which arcing does not occur in the mechanical switch section 110, it is possible to shorten the cutoff time compared to a case where the DC current is cut off by utilizing a cooling effect with hydrogen gas and an arc stretching effect with a magnetic field in a mechanical relay, for example. Therefore, when a large current is cut off in the switch apparatus 10, the interval from when the first semiconductor switch section 120 is turned OFF to when the second semiconductor switch section 130 is turned OFF after the mechanical switch section 110 has been turned OFF is shortened, and the current increase in the second semiconductor switch section 130 is suppressed. Accordingly, the switch apparatus 10 can reduce the current capacity of the second semiconductor switch section 130, thereby making it possible to decrease the size and lower the cost.

In the first embodiment described above, a configuration is described in which the operation of the switch apparatus 10 is controlled by the external control apparatus 5. Instead, the switch apparatus 10 may be packaged to include the control apparatus 5 therein. The above is also true in the following embodiments.

In the first embodiment described above, the first semiconductor switch section 120 and the second semiconductor switch section 130 of the switch apparatus 10 each include a single semiconductor switch element. Instead, the first semiconductor switch section 120 may include a plurality of first semiconductor switches connected in parallel between the first terminal 21 and the second terminal 22. In this way, first semiconductor switches with small rated currents can be used as the first semiconductor switch section 120, thereby making it possible to reduce the size and lower the cost, and to improve the redundancy. Furthermore, the second semiconductor switch section 130 may include a plurality of second semiconductor switches connected in series between the first terminal 21 and the second terminal 22. In this way, second semiconductor switches with low withstand voltages can be used as the second semiconductor switch section 130, thereby making it possible to reduce the size and lower the cost. In this case, the withstand voltage of each of the plurality of first semiconductor switches may be lower than the withstand voltage of each of the plurality of second semiconductor switches and higher than the sum of the ON voltages of the plurality of second semiconductor switches. Margins may be provided between the voltages in these ratios. In this way, it is possible to control the ON/OFF operations in the same manner as in the switch apparatus 10 of the first embodiment. This above is also true in the following embodiments.

In the first embodiment described above, when switching the state between the first terminal 21 and the second terminal 22 from the connected state to the disconnected state, the switch apparatus 10 turns ON the second semiconductor switch section 130, shifts the timing by the time difference Δt1, and then turns ON the mechanical switch section 110 from the control circuit 40. Instead of or in addition to this, the switch apparatus 10 may include a voltmeter that detects a potential difference between the first terminal 21 that is the input side of the second semiconductor switch section 130 and the second terminal 22 that is the output side of the second semiconductor switch section 130, and when switching the state between the first terminal 21 and the second terminal 22 from the connected state to the disconnected state, after turning ON the second semiconductor switch section 130, turn ON the mechanical switch section 110 in response to the potential difference between the first terminal 21 and the second terminal 22 detected by the voltmeter becoming less than or equal to a reference. In this way, by setting the reference to be the ON voltage of the IGBT of the second semiconductor switch section 130, for example, when the mechanical switch section 110 is turned ON, it is possible to reliably set the DC voltage applied to the first semiconductor switch section 120 to be less than or equal to this ON voltage, thereby reliably preventing the occurrence of overvoltage breakdown in the first semiconductor switch section 120. The above is also true for the following embodiments.

In the first embodiment, when switching the state between the first terminal 21 and the second terminal 22 from the connected state to the disconnected state, after turning OFF the first semiconductor switch section 120, the switch apparatus 10 shifts the timing by the time difference Δt2, and then turns OFF the mechanical switch section 110 from the control circuit 40. Instead of or in addition to this, the switch apparatus 10 may include an ammeter that detects the current flowing through the first semiconductor switch section 120, and when switching the state between the first terminal 21 and the second terminal 22 from the connected state to the disconnected state, after turning OFF the first semiconductor switch section 120, turn OFF the mechanical switch section 110 in response to the current of the first semiconductor switch section 120 detected by the ammeter becoming less than or equal to a predetermined value.

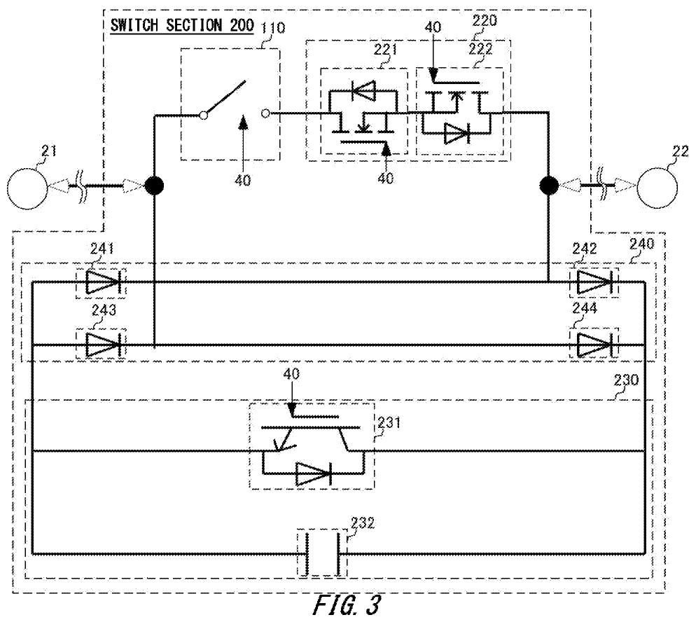

FIG. 3 is a schematic circuit diagram of a switch section 200 according to a second embodiment. The switch apparatus 10 according to the embodiment may be applied to a switchboard or the like that handles AC current and, as examples, an AC voltage of 100 V or 200 V is applied thereto when in commercial use, and an AC voltage of 3.3 kV or 6.6 kV is applied thereto when connected to a high-voltage line. The switch apparatus 10 according to the present embodiment conducts or cuts off the AC current that attempts to flow from the first terminal 21 to the second terminal 22, by providing a connection or a disconnect between the first terminal 21 and the second terminal 22.

The difference between the switch apparatus 10 according to the present embodiment and the switch apparatus 10 according to the first embodiment is that the switch apparatus 10 according to the present embodiment includes a switch section 200 instead of the switch section 100, and all other configurational elements are the same. In the present embodiment, configurational elements that are the same as those in the switch apparatus 10 according to the first embodiment are given the same reference numerals, and redundant descriptions are omitted. This is also true for the following embodiments.

The switch section 200 includes the mechanical switch section 110, a first semiconductor switch section 220, a diode bridge 240, and a second semiconductor switch section 230.

The first semiconductor switch section 220 is connected in series to the mechanical switch section 110, between the first terminal 21 and the second terminal 22. The first semiconductor switch section 220 includes a first semiconductor switch 221 and a first semiconductor switch 222 that are connected in anti-series between the first terminal 21 and the second terminal 22. The first semiconductor switch 221 and the first semiconductor switch 222 each include a set of a semiconductor element and a diode connected in parallel between the first terminal 21 and the second terminal 22. The set of the semiconductor switch element and the diode includes, for example, a low-voltage MOSFET and a body diode housed in the low-voltage MOSFET or a diode connected in antiparallel to the low-voltage MOSFET, in the same manner as in the first semiconductor switch section 120 of the first embodiment. The drain of the low-voltage MOSFET of the first semiconductor switch 221 is connected to the mechanical switch section 110, the source of the low-voltage MOSFET of the first semiconductor switch 221 is connected to the source of the low-voltage MOSFET of the first semiconductor switch 222, and the drain of the low-voltage MOSFET of the first semiconductor switch 222 is connected to the second terminal 22. The gates of the first semiconductor switch 221 and the first semiconductor switch 222 are both connected to the control circuit 40.

The diode bridge 240 is connected in parallel with the mechanical switch section 110 and the first semiconductor switch section 220, between the first terminal 21 and the second terminal 22. The diode bridge 240 includes a diode 241, a diode 242, a diode 243, and a diode 244, and forms a rectifier circuit that causes the AC current to flow in only one direction by performing full-wave rectification, using these four diodes 241 and the like.

The second semiconductor switch section 230 is connected in parallel with the diode bridge 240 on the rectification side of the diode bridge 240, between the first terminal 21 and the second terminal 22. The second semiconductor switch section 230 includes a second semiconductor switch 231 and a capacitor 232 connected in parallel between the first terminal 21 and the second terminal 22. The capacitor 232 is a soft-switching capacitor, and forms a so-called snubber circuit. The second semiconductor switch 231 includes a set of a semiconductor switch element and a diode connected in antiparallel between the first terminal 21 and the second terminal 22. This set of the semiconductor switch element and the diode includes a set of an IGBT and a diode connected in antiparallel with the IGBT, for example. The IGBT of the second semiconductor switch section 230 has its collector connected to the second terminal 22, its emitter connected to the first terminal 21, and its gate connected to the control circuit 40.

The IGBT is connected via the diode bridge 240, and therefore can be applied to either a positive or negative current, i.e. it is possible to switch the AC current with only one IGBT. Therefore, it is possible to avoid an increase in the number of relatively high-cost IGBTs, thereby decreasing the size and lowering the cost. In a case where the switch apparatus 10 is a circuit breaker or the like that conducts a relatively large current, two IGBTs must be used if the switch section 200 is configured without the diode bridge 240. Therefore, since two IGBTs having saturation characteristics compatible with a large current are necessary, the cost increases significantly. In contrast to this, according to the present embodiment, as shown in FIG. 3, by configuring the switch section 200 to include the diode bridge 240, it is possible to significantly lower the cost.

Concerning the first semiconductor switch section 220, the control circuit 40 outputs a common control signal to the first semiconductor switch 221 and the first semiconductor switch 222, i.e. the control circuit 40 controls the ON/OFF operations of the first semiconductor switch 221 and the first semiconductor switch 222 in conjunction. More specifically, in the normal case, the control circuit 40 controls both the first semiconductor switch 221 and the first semiconductor switch 222 to be in the ON state, and therefore the current flows through each low-voltage MOSFET side not only when the AC current flows in one direction from the drain to the source but also when the AC current flows in a direction from the source to the drain, due to so-called synchronous rectification. Therefore, the current conduction loss in the first semiconductor switch section 220 is still small. When cutting off the AC current with the switch section 200, the control circuit 40 performs control to turn OFF both the first semiconductor switch 221 and the first semiconductor switch 222 before turning OFF the mechanical switch section 110 and the second semiconductor switch section 230, and therefore the AC current that flowed through the first semiconductor switch section 220 side is commutated to the second semiconductor switch section 230 side.

Concerning the second semiconductor switch section 230, in the normal case, the control circuit 40 performs control to set the second semiconductor switch section 230 to the ON state. However, since the ON voltage of the second semiconductor switch section 230 is higher than the sum of the ON voltages of the mechanical switch section 110 and the first semiconductor switch section 220, the AC current barely flows through the second semiconductor switch section 230. Furthermore, when cutting off the AC current with the switch section 200, the control circuit 40 performs control to turn OFF the second semiconductor switch section 230 after the AC current that flowed through the first semiconductor switch section 220 side has been commutated to the second semiconductor switch section 230 side and has flowed through the second semiconductor switch section 230. In the normal case, the control circuit 40 may set the second semiconductor switch section 230 to the OFF state while the AC current is flowing through the first semiconductor switch section 220 side, and when cutting of the AC current with the switch section 200, may perform control to turn OFF the first semiconductor switch section 220 after turning ON the second semiconductor switch section 230, thereby commutating and cutting off the AC current in the same manner as above.

According to the switch apparatus 10 of the second embodiment described above, in the same manner as the switch apparatus 10 of the first embodiment, with the first semiconductor switch section 220, the mechanical switch section 110, and the second semiconductor switch section 230 in the OFF state, when switching the state between the first terminal 21 and the second terminal 22 from the disconnected state to the connected state, the second semiconductor switch section 230, the mechanical switch section 110, and the first semiconductor switch section 220 are turned ON in the stated order. Furthermore, according to this switch apparatus 10, with the first semiconductor switch section 220, the mechanical switch section 110, and the second semiconductor switch section 230 in the ON state, when switching the state between the first terminal 21 and the second terminal 22 from the connected state to the disconnected state, the first semiconductor switch section 220, the mechanical switch section 110, and the second semiconductor switch section 230 are turned OFF in the stated order. In this way, this switch apparatus 10 realizes the same effects as the switch apparatus 10 of the first embodiment. Furthermore, this switch apparatus 10 includes the diode bridge 240 connected in parallel with the second semiconductor switch section 230, and therefore realizes the function of an AC bidirectional switch, while also avoiding an increase in the number of relatively high-price IGBTs, thereby making it possible to decrease the size and lower the cost.

In the second embodiment described above, the first semiconductor switch section 220 of the switch apparatus 10 includes two switches, which are the first semiconductor switch 221 and the first semiconductor switch 222, connected in anti-series, and the second semiconductor switch section 230 includes a single semiconductor switch element. Instead, the first semiconductor switch section 220 may include a plurality of first semiconductor switches connected in parallel between the first terminal 21 and the second terminal 22. Furthermore, the second semiconductor switch section 230 may include a plurality of second semiconductor switches connected in series between the first terminal 21 and the second terminal 22. In this case, the withstand voltage of each of the plurality of first semiconductor switches may be lower than the withstand voltage of each of the plurality of second semiconductor switches and higher than the sum of the ON voltages of the plurality of second semiconductor switches. Margins may be provided between the voltages in these ratios. In this way, it is possible for this switch apparatus 10 to realize the same effect as the switch apparatus 10 of the first embodiment.

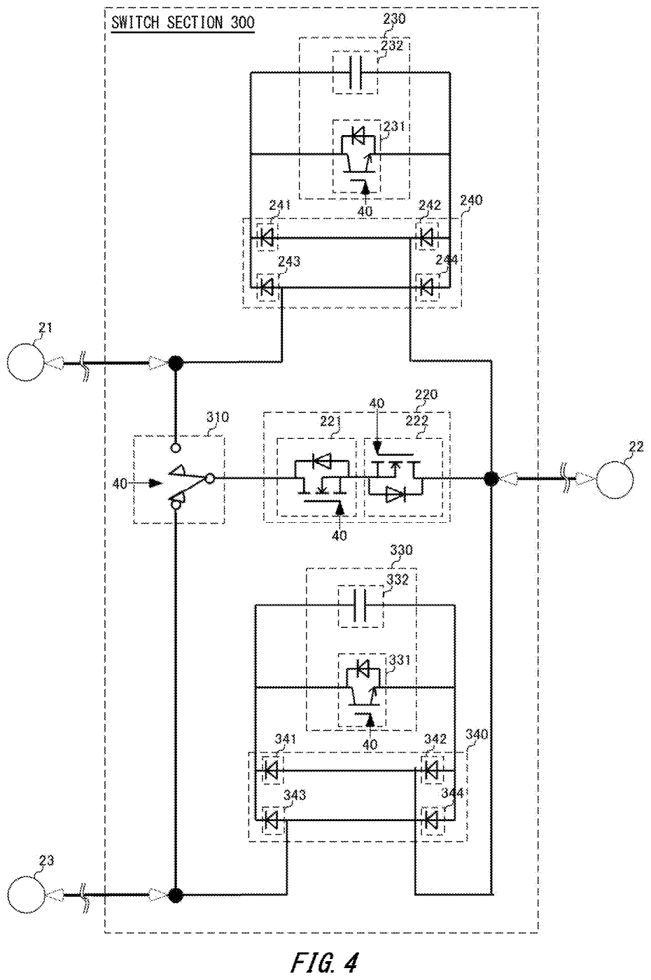

FIG. 4 is a schematic diagram of a switch section 300 according to a third embodiment. In the same manner as the second embodiment, the switch apparatus 10 in the present embodiment may be applied to a switchboard or the like that handles AC current, and may be used for switching between main power and auxiliary power, for example. The difference between the switch apparatus 10 according to the present embodiment and the switch apparatus 10 according to the second embodiment is that the switch apparatus 10 of the present embodiment includes a third terminal 23 in addition to the first terminal 21 and the second terminal 22 and also includes a switch section 300 instead of the switch section 200, and all other configurational elements are the same. The third terminal 23 is an example of a second input terminal.

By providing a connection or a disconnect between the first terminal 21 and the second terminal 22 and between the third terminal 23 and the second terminal 22, the switch apparatus 10 according to the present embodiment switches the state between the first terminal 21 and the second terminal 22 from the connected state to the disconnected state and switches the state between the third terminal 23 and the second terminal 22 from the disconnected state to the connected state, or in an opposite manner, switches the state between the third terminal 23 and the second terminal 22 from the connected state to the disconnected state and switches the state between the first terminal 21 and the second terminal 22 from the disconnected state to the connected state. In this way, the switch apparatus 10 switches the AC current attempting to flow from the first terminal 21 to the second terminal 22 and the AC current attempting to flow from the third terminal 23 to the second terminal 22.

The switch section 300 includes a mechanical switch section 310, the first semiconductor switch section 220, the second semiconductor switch section 230, the diode bridge 240, a diode bridge 340, and a third semiconductor switch section 330. The arrangement of the mechanical switch section 310, and the arrangement and configuration of the first semiconductor switch section 220, the second semiconductor switch section 230, and the diode bridge 240 are the same as the corresponding configurational elements in the second embodiment.

The mechanical switch section 310 is connected between the first terminal 21 and third terminal 23 and the second terminal 22. The mechanical switch section 310 differs from the mechanical switch section 110 in the first embodiment in that the mechanical switch section 310 switches between a connected state between the first terminal 21 and the first semiconductor switch section 220 and a connected state between the third terminal 23 and the first semiconductor switch section 220, in the manner of a double-headed mechanical switch, for example.

The first semiconductor switch section 220 is connected in series with the mechanical switch section 310, between the first terminal 21 and third terminal 23 and the second terminal 22. Furthermore, the second semiconductor switch section 230 is connected in parallel with the mechanical switch section 310 and the first semiconductor switch section 220, between the first terminal 21 and the second terminal 22.

The diode bridge 340 may have the same configuration as the diode bridge 240, and is connected in parallel with the mechanical switch section 310 and the first semiconductor switch section 220, between the third terminal 23 and the second terminal 22. The diode bridge 340 includes a diode 341, a diode 342, a diode 343, and a diode 344, and forms a rectifier circuit that causes the AC current to flow in only one direction by performing full-wave rectification, using these four diodes 341 and the like.

The third semiconductor switch section 330 may have the same configuration as the second semiconductor switch section 230, is connected in parallel with the mechanical switch section 310 and the first semiconductor switch section 220 between the third terminal 23 and the second terminal 22, and is also connected in parallel with the diode bridge 340 on the rectification side of the diode bridge 340. The third semiconductor switch section 330 includes a third semiconductor switch 331 and a capacitor 332 connected in parallel, between the third terminal 23 and the second terminal 22. The third semiconductor switch 331 includes a set of a semiconductor switch element and a diode connected in antiparallel between the third terminal 23 and the second terminal 22. This set of the semiconductor switch element and the diode includes a set of an IGBT and a diode connected in antiparallel with the IGBT, for example. The IGBT of the third semiconductor switch section 330 has its collector connected to the second terminal 22, its emitter connected to the third terminal 23, and its gate connected to the control circuit 40. The third semiconductor switch section 330 may include a GTO thyristor, a WBG semiconductor, or the like.

Concerning the mechanical switch section 310, when setting the connected state between the first terminal 21 and the second terminal 22 and setting the disconnected state between the third terminal 23 and the second terminal 22, the control circuit 40 controls the mechanical switch section 310 to set the connected state between the first terminal 21 and the first semiconductor switch section 220, thereby causing the AC current to flow between the first terminal 21 and the second terminal 22. When setting the disconnected state between the first terminal 21 and the second terminal 22 and setting the connected state between the third terminal 23 and the second terminal 22, the control circuit 40 controls the mechanical switch section 310 to set the connected state between the third terminal 23 and the first semiconductor switch section 220, thereby causing the AC current to flow between the third terminal 23 and the second terminal 22. When switching between these two states, the mechanical switch section 310 is controlled by the control circuit 40 to perform switching after the AC current has been commutated from the first semiconductor switch section 220 side to either the second semiconductor switch section 230 side or the third semiconductor switch section 330 side. When performing control in this manner, arcing does not occur in the mechanical switch section 310. However, while either of the second semiconductor switch section 230 and the third semiconductor switch section 330 is in the ON state, the voltage between the corresponding first terminal 21 or third terminal 23 and the second terminal 22 is approximately tens of volts, and therefore, instead of the above control, the current may be cut off by the mechanical switch section 310 by switching the mechanical switch section 310 before the commutation described above. In this case, the switch section 300 may additionally have a configuration for protecting the mechanical switch section 310 from the arcing generated by the mechanical switch section 310.

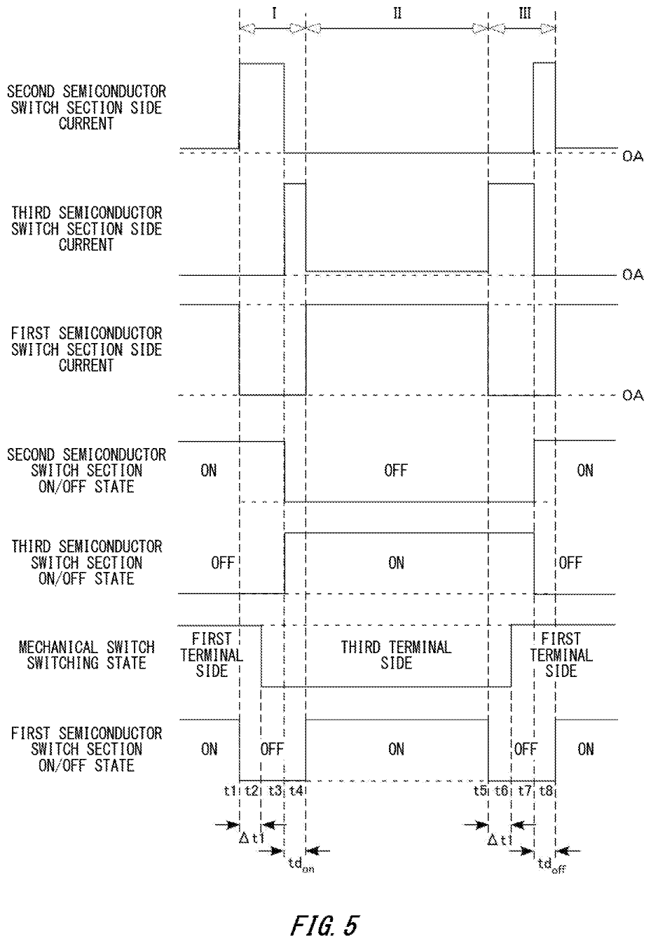

FIG. 5 is a timing chart showing the operation of the switch section 300 according to the third embodiment. FIG. 5 shows the passage of time in the horizontal direction, and shows the transitioning over time of the current on the second semiconductor switch section 230 side, the current on the third semiconductor switch section 330 side, the current on the first semiconductor switch section 220 side, the ON/OFF state of the second semiconductor switch section 230, the ON/OFF state of the third semiconductor switch section 330, the switching state of the mechanical switch section 310, and the ON/OFF state of the first semiconductor switch section 220 in the stated order from the top in the vertical direction. Furthermore, FIG. 5 shows intervals (I), (II), and (III), obtained by dividing the elapsed time into three main intervals, in the stated order from the left.

The interval (I) is an interval during which the state between the first terminal 21 and the second terminal 22 is switched from the connected state to the disconnected state and the state between the third terminal 23 and the second terminal 22 is switched from the disconnected state to the connected state, due to the mechanical switch section 310 in the switch section 300 switching from the connected state between the first terminal 21 and the first semiconductor switch section 220 to the connected state between the third terminal 23 and the first semiconductor switch section 220. The interval (II) is an interval during which the AC current is regularly conducted between the third terminal 23 and the second terminal 22 by the switch section 300. The interval (III) is an interval during which the state between the first terminal 21 and the second terminal 22 is switched from the disconnected state to the connected state and the state between the third terminal 23 and the second terminal 22 is switched from the connected state to the disconnected state, due to the mechanical switch section 310 in the switch section 300 switching from the connected state between the third terminal 23 and the first semiconductor switch section 220 to the connected state between the first terminal 21 and the first semiconductor switch section 220.

In the time sequence in FIG. 5, the intervals before the interval (I) and after the interval (III) are intervals during which the AC current is regularly conducted between the first terminal 21 and the second terminal 22 due to the switch section 300, and any of the intervals (I), (II), and (III) may be included in the intervals not shown in the drawing.

Before entering the interval (I), the first semiconductor switch section 220 and the second semiconductor switch section 230 are in the ON state and the mechanical switch section 310 has set the connected state between the first terminal 21 and the first semiconductor switch section 220. At the initial timing t1 of the interval (I), the gate voltage of the low-voltage MOSFET of the first semiconductor switch section 220 is controlled from the control circuit 40 to turn OFF the first semiconductor switch section 220. The low-voltage MOSFET has a switching speed of tens of nanoseconds, and can therefore quickly enter the OFF state. Due to the first semiconductor switch section 220 entering the OFF state, the first semiconductor switch section 220 side is completely cut off and the AC current that was flowing through the first semiconductor switch section 220 side is commutated to the second semiconductor switch section 230 side. By turning OFF the first semiconductor switch section 220 while keeping the mechanical switch section 310 and the second semiconductor switch section 230 in the ON state, the AC voltage applied to the first semiconductor switch section 220 is approximately from several volts to tens of volts, which is the ON voltage of the IGBT of the second semiconductor switch section 230, and therefore it is possible to use a low-voltage MOSFET in the first semiconductor switch section 220.

The next timing t2 in the interval (I) has a time difference Δt1 relative to the timing t1. The time difference Δt1 only needs to be enough to ensure the time necessary for the low-voltage MOSFET of the first semiconductor switch section 220 to turn OFF, i.e. the time until the turn-OFF operation is completed and the AC current that was flowing through the first semiconductor switch section 220 side is commutated to the second semiconductor switch section 230 side. As an example, the time difference Δt1 is approximately from 1 μs to 2 μs. At the timing t2, the mechanical switch section 310 is switched from the control circuit 40, thereby causing the mechanical switch section 310 to switch to the connected state between the third terminal 23 and the first semiconductor switch section 220. At this time, the AC current does not flow through the first semiconductor switch section 220 side, and therefore arcing does not occur in the mechanical switch section 310.

At the next timing t3 in the interval (I), the gate voltages of the IGBT of the second semiconductor switch section 230 and the IGBT of the third semiconductor switch section 330 are each controlled from the control circuit 40 to turn ON the second semiconductor switch section 230 and turn OFF the third semiconductor switch section 330, thereby completely cutting off the AC current flowing between the first terminal 21 and the second terminal 22 and also causing the AC current to be conducted between the third terminal 23 and the second terminal 22. The IGBT of the second semiconductor switch section 230 and the IGBT of the third semiconductor switch section 330 are each a semiconductor switch element capable of a relatively high-speed switching operation, and can therefore quickly enter the ON state or the OFF state, thereby making it possible to increase the speeds of the OFF operation of the entire switch apparatus 10 and the ON operation of one system when overcurrent occurs in another system. In other words, it is possible to switch at high speed from a system in which an abnormality occurred to another system operating normally. Furthermore, if there is a time span during which the second semiconductor switch section 230 and the third semiconductor switch section 330 are both in the ON state when an accident point occurs in a system through the first terminal 21, the accidental current flows from the first terminal 21 via the second semiconductor switch section 230 and the third semiconductor switch section 330, but due to the control described above, the switch apparatus 10 can prevent this accidental current from flowing sideways.

The initial timing t4 in the interval (II) has a delay time of tdₒₙ relative to the timing t3 in the interval (I). The delay time tdₒₙ only needs to be enough to ensure the time necessary for the IGBT of the third semiconductor switch section 330 to turn ON, i.e. the time until the turn-ON operation is completed and the regular AC current is conducted by the IGBT of the third semiconductor switch section 330. The delay time tdₒₙ is approximately 1 μs to 2 μs. At the timing t4, the gate voltage of the low-voltage MOSFET of the first semiconductor switch section 220 is controlled from the control circuit 40 to turn ON the first semiconductor switch section 220. Since the sum of the ON voltages of the mechanical switch section 310 and the first semiconductor switch section 220 is lower than the ON voltage of the third semiconductor switch section 330, at the timing t4, the AC current that was flowing through the third semiconductor switch section 330 side is commutated to the first semiconductor switch section 220 side, and almost no AC current flows through the third semiconductor switch section 330 side. At least between the timing t2 and the timing t3, the high voltage of the system is applied to the first semiconductor switch 221 of the first semiconductor switch section 220 via the third terminal 23, and therefore the first semiconductor switch 221 is preferably a semiconductor switch element capable of high-speed switching with a high withstand voltage.

In the interval (III), the switch apparatus 10 performs control that is the opposite of the control described above performed in the interval (I). Before entering the interval (III), the first semiconductor switch section 220 and the third semiconductor switch section 330 are in the ON state, and the mechanical switch section 310 sets the connected state between the third terminal 23 and the first semiconductor switch section 220. At the initial timing t5 of the interval (III), the gate voltage of the low-voltage MOSFET of the first semiconductor switch section 220 is controlled from the control circuit 40 to turn OFF the first semiconductor switch section 220. Due to the first semiconductor switch section 220 entering the OFF state, the first semiconductor switch section 220 side is completely cut off, and the AC current that was flowing on the first semiconductor switch section 220 side is commutated to the third semiconductor switch section 330 side. By turning OFF the first semiconductor switch section 220 while keeping the mechanical switch section 310 and the third semiconductor switch section 330 in the ON state, the AC voltage applied to the first semiconductor switch section 220 is approximately tens of volts, which is the ON voltage of the IGBT of the third semiconductor switch section 330, and therefore it is possible to use a low-voltage MOSFET in the first semiconductor switch section 220.

The next timing t6 in the interval (III) has a time difference Δt1 relative to the timing t1. The time difference Δt1 only needs to be enough to ensure the time necessary for the low-voltage MOSFET of the first semiconductor switch section 220 to turn OFF, i.e. the time until the turn-OFF operation is completed and the AC current that was flowing through the first semiconductor switch section 220 side is commutated to the third semiconductor switch section 330 side. At the timing t6, the mechanical switch section 310 is switched from the control circuit 40, thereby causing the mechanical switch section 310 to switch to the connected state between the first terminal 21 and the first semiconductor switch section 220. At this time, the AC current does not flow through the first semiconductor switch section 220 side, and therefore arcing does not occur in the mechanical switch section 310.

At the next timing t7 in the interval (III), the gate voltages of the IGBT of the third semiconductor switch section 330 and the IGBT of the second semiconductor switch section 230 are each controlled from the control circuit 40 to turn OFF the third semiconductor switch section 330 and turn ON the second semiconductor switch section 230, thereby completely cutting off the AC current flowing between the third terminal 23 and the second terminal 22 and also causing the AC current to be conducted between the first terminal 21 and the second terminal 22.

The next timing t8 in the interval (III) has a delay time td_{off} relative to the timing t7. The delay time td_{off} only needs to be enough to ensure the time needed for the IGBT of the second semiconductor switch section 230 to turn ON, i.e. the time until the turn-ON operation is complete and the regular AC current is conducted by the IGBT of the second semiconductor switch section 230. The delay time td_{off} is approximately from 1 μs to 2 μs, for example. At the timing t8, the gate voltage of the low-voltage MOSFET of the first semiconductor switch section 220 is controlled form the control circuit 40 to turn ON the first semiconductor switch section 220. Since the sum of the ON voltages of the mechanical switch section 310 and the first semiconductor switch section 220 is lower than the ON voltage of the second semiconductor switch section 230, at the timing t8, the AC current that was flowing on the second semiconductor switch section 230 side is commutated to the first semiconductor switch section 220 side, and the AC current barely flows through the second semiconductor switch section 230 side.

According to the switch apparatus 10 of the third embodiment described above, the same effects as the switch apparatuses 10 according to the first embodiment and the second embodiment are realized. Furthermore, according to this switch apparatus 10, the mechanical switch section 310 and the first semiconductor switch section 220 connected in series can be shared by the first terminal 21 side and the third terminal 23 side, thereby making it possible to reduce the size and lower the cost. Yet further, according to this switch apparatus 10, the switch apparatus 10 is connected to a plurality of different systems, and not only is it possible to perform the OFF operation of the entire switch apparatus 10 and the ON operation of one of the systems at high speed when overcurrent occurs in the other system, but it is also possible to prevent the horizontal flow of accidental voltage from the other system to the one system.

In the third embodiment described above, the difference between the timing t2 and the timing t3 may be omitted, or the timing t2 and the timing t3 may be inverted. Furthermore, during the intervals from the timing t2 to the timing t3 and to the timing t4, the mechanical switch section 310 may set the disconnected state between the first semiconductor switch section 220 and each of the first terminal 21 and the third terminal 23. More specifically, according to the control of the control apparatus 5 via the control circuit 40, with the first semiconductor switch section 220 and the second semiconductor switch section 230 in the ON state and the mechanical switch section 310 setting the connected state between the first terminal 21 and the first semiconductor switch section 220, when switching the state between the first terminal 21 and the second terminal 22 from the connected state to the disconnected state and switching the state between the third terminal 23 and the second terminal 22 from the disconnected state to the connected state, the first semiconductor switch section 220 may be turned OFF, after which the mechanical switch section 310 may switch to the disconnected state between the first semiconductor switch section 220 and each of the first terminal 21 and the third terminal 23, then the second semiconductor switch section 230 may be turned OFF and the third semiconductor switch section 330 may be turned ON, then the mechanical switch section 310 may switch to the connected state between the third terminal 23 and the first semiconductor switch section 220, and then the first semiconductor switch section 220 may be turned ON.

Furthermore, in the case described above, the switch apparatus 10 may include a voltmeter that detects the potential difference between the third terminal 23 and the second terminal 22 connected to the third semiconductor switch section 330 and, according to the control by the control apparatus 5 via the control circuit 40, may turn ON the third semiconductor switch section 330 and then have the mechanical switch section 310 switch to the connected state between the third terminal 23 and the first semiconductor switch section 220 in response to the potential difference between the third terminal 23 and the second terminal 22 becoming less than or equal to a reference.

In the plurality of embodiments described above, the second semiconductor switch section 230 or the third semiconductor switch section 330 includes an IGBT, but a power MOSFET may be used instead of the IGBT if the intended use demands a higher switching speed than when an IGBT is used and it is acceptable for the withstand voltage to be low. In this case, the current conduction loss may be reduced by so-called synchronous rectification, by providing a connection such that the current flows in the power MOSFET from the source to the drain.

In the second embodiment and the third embodiment described above, the second semiconductor switch section 230 or the third semiconductor switch section 330 includes an IGBT in which a diode is connected in antiparallel, but may instead use a reverse blocking IGBT (RB-IGBT).

### LIST OF REFERENCE NUMERALS

5: control apparatus, 10: switch apparatus, 21: first terminal, 22: second terminal, 23: third terminal, 25: control terminal, 30: current detecting section, 40: control circuit, 41: protection circuit, 42: pulse distribution circuit, 43: drive circuit, 100, 200, 300: switch section, 110, 310: mechanical switch section, 120, 220: first semiconductor switch section, 130, 230: second semiconductor switch section, 221, 222: first semiconductor switch, 231: second semiconductor switch, 232: capacitor, 240, 340: diode bridge, 241, 242, 243, 244, 341, 342, 343, 344: diode, 330: third semiconductor switch section, 331: third semiconductor switch, 332: capacitor

What is claimed is:

1. A switch apparatus that provides a connection or a disconnect between an input terminal and an output terminal, comprising:
a mechanical switch section and a first semiconductor switch section that are connected in series, between the input terminal and the output terminal;
a second semiconductor switch section that is connected in parallel with the mechanical switch section and the first semiconductor switch section, between the input terminal and the output terminal; and
a switch control section that individually controls respective ON/OFF timings of the first semiconductor switch section and the second semiconductor switch section and an open/close timing of the mechanical switch section.

2. The switch apparatus according to claim 1, further comprising a current detecting section provided between the input terminal and the output terminal, wherein the switch control section includes:
a protection circuit that outputs OFF instructions when overcurrent is detected in response to a signal from the current detecting section;
a pulse distribution circuit that, based on a signal from outside, outputs a predetermined pulse signal for opening/closing the mechanical switch section and turning ON/OFF each of the first semiconductor switch section and the second semiconductor switch section, and when the OFF instructions are input from the protection circuit, outputs a predetermined pulse signal for closing the mechanical switch section and turning OFF each of the first semiconductor switch section and the second semiconductor switch section, regardless of the signal from the outside; and
a drive circuit that, based on the pulse signal input from the pulse distribution circuit, outputs a signal for opening/closing the mechanical switch section and gate voltages for respectively turning ON/OFF each of the first semiconductor switch section and the second semiconductor switch section.

3. The switch apparatus according to claim 1, wherein
a withstand voltage of the first semiconductor switch section is higher than an ON voltage of the second semiconductor switch section.

4. The switch apparatus according to claim 3, wherein
the first semiconductor switch section includes a plurality of first semiconductor switches connected in parallel between the input terminal and the output terminal, and the second semiconductor switch section includes a plurality of second semiconductor switches connected in series between the input terminal and the output terminal, and
a withstand voltage of each of the plurality of the first semiconductor switches is higher than a sum of ON voltages of the plurality of second semiconductor switches.

5. The switch apparatus according to claim 1, wherein
the switch control section, with each of the first semiconductor switch section, the mechanical switch section, and the second semiconductor switch section in the ON state, when switching a state between the input terminal and the output terminal from a connected state to a disconnected state, turns OFF the first semiconductor switch section, the mechanical switch section, and the second semiconductor switch section in the stated order.

6. The switch apparatus according to claim 5, wherein
the switch control section, when switching the state between the input terminal and the output terminal from the connected state to the disconnected state, turns OFF the first semiconductor switch section, and then turns OFF the mechanical switch section in response to current of the first semiconductor switch section becoming less than or equal to a predetermined value.

7. The switch apparatus according to claim 1, wherein
the switch control section, with each of the first semiconductor switch section, the mechanical switch section, and the second semiconductor switch section in the OFF state, when switching a state between the input terminal and the output terminal from a disconnected state to a connected state, turns ON the second semiconductor switch section, the mechanical switch section, and the first semiconductor switch section in the stated order.

8. The switch apparatus according to claim 7, wherein
the switch control section turns ON the second semiconductor switch section, and then turns ON the mechanical switch section in response to a potential difference between the input terminal and the output terminal becoming less than or equal to a reference.

9. A switch apparatus comprising:
a mechanical switch that switches between (i) a connected state between a first input terminal and an output terminal and (ii) a connected state between a second input terminal and the output terminal;
a first semiconductor switch section that is connected in series with the mechanical switch, between the first input terminal and the output terminal and between the second input terminal and the output terminal;
a second semiconductor switch section that is connected in parallel with the mechanical switch and the first semiconductor switch section, between the first input terminal and the output terminal;
a third semiconductor switch section that is connected in parallel with the mechanical switch and the first semiconductor switch section, between the second input terminal and the output terminal; and
a switch control section that individually controls respective ON/OFF timings of the first semiconductor switch section, the second semiconductor switch section, and the third semiconductor switch section and an open/close timing of the mechanical switch.

10. The switch apparatus according to claim 9, wherein
the switch control section, with the first semiconductor switch section and the second semiconductor switch section in an ON state and the mechanical switch providing a connected state between the first input terminal and the first semiconductor switch section, when switching the state between the first input terminal and the output terminal from the connected state to a disconnected state and switching the state between the second input terminal and the output terminal from the disconnected state to the connected state, turns OFF the first semiconductor switch section, then causes the mechanical switch to switch to the connected state between the second input terminal and the first semiconductor switch section, then turns OFF the second semiconductor switch section and turns ON the third semiconductor switch section, and then turns ON the first semiconductor switch section.

11. The switch apparatus according to claim 9, wherein
the switch control section, with the first semiconductor switch section and the second semiconductor switch section in the ON state and the mechanical switch providing the connected state between the first input terminal and the first semiconductor switch section, when switching the state between the first input terminal and the output terminal from the connected state to a disconnected state and switching the state between the second input terminal and the output terminal from the disconnected state to the connected state, turns OFF the first semiconductor switch section, then causes the mechanical switch to switch to the disconnected state between the first input terminal and the first semiconductor switch section and between the second input terminal and the first semiconductor switch section, then turns OFF the second semiconductor switch section and turns ON the third semiconductor switch section, then causes the mechanical switch to switch to the connected state between the second input terminal and the first semiconductor switch section, and then turns ON the first semiconductor switch section.

12. The switch apparatus according to claim 11, wherein
the switch control section turns ON the third semiconductor switch section, and then causes the mechanical switch to switch to the connected state between the second input terminal and the first semiconductor switch section in response to a potential difference between the second input terminal and the output terminal becoming less than or equal to a reference.

13. The switch apparatus according to claim 1, wherein
the first semiconductor switch section includes a plurality of first semiconductor switches connected in anti-series between the input terminal and the output terminal, and each first semiconductor switch includes a set of a semiconductor switch element and a diode connected in antiparallel between the input terminal and the output terminal, and
the switch apparatus further comprises a diode bridge that is connected in parallel with the second semiconductor switch section, between the input terminal and the output terminal.

14. The switch apparatus according to claim 9, wherein
the first semiconductor switch section includes a plurality of first semiconductor switches connected in anti-series between the first input terminal and the output terminal, and each first semiconductor switch includes a set of a semiconductor switch element and a diode connected in antiparallel between the first input terminal and the output terminal, and
the switch apparatus further comprises:
a first diode bridge connected in parallel with the second semiconductor switch section, between the first input terminal and the output terminal; and
a second diode bridge connected in parallel with the third semiconductor switch section, between the second input terminal and the output terminal.

15. The switch apparatus according to claim 1, wherein
the first semiconductor switch section includes a MOSFET, and the second semiconductor switch section includes at least one of an IGBT, a GTO thyristor, and a WBG semiconductor.

16. The switch apparatus according to claim 9, wherein
the first semiconductor switch section includes a MOSFET, and at least one of the second semiconductor switch section and the third semiconductor switch section includes at least one of an IGBT, a GTO thyristor, and a WBG semiconductor.
